(19) United States
(12) Patent Application Publication
(10) Pub. No.: US 2009/0061546 A1
(43) Pub. Date: Mar. 5, 2009

(54) METHOD FOR SETTING PREDEFINABLE PARAMETERS

(76) Inventors: Herbert Labitzke, Markgroeningen (DE); Guenter Nasswetter, Gomaringen (DE); Helmut Suelzle, Freiberg (DE)

Correspondence Address: KENYON & KENYON LLP, ONE BROADWAY, NEW YORK, NY, 10004, US

(21) Appl. No.: 11/658,466

(22) PCT Filed: Jul. 15, 2005
(86) PCT No.: PCT/EP2005/053403

§ 371 Date: Oct. 15, 2008

(30) Foreign Application Priority Data
Jul. 31, 2004 (DE) 10 2004 037 259.4

(51) Int. Cl. H01L 21/66

(52) U.S. Cl. 438/17; 257/E21.531

(57) ABSTRACT

A method for setting predefinable parameters is described, in which for an electronic component, for example a voltage regulator having at least one integrated circuit, the latter has an external connection, via which it is connectable to a programming device. For the latter, a so-called zero programming is provided in the manufacture of the integrated circuit, and predefinable parameters or settings are programmed in following the completion of the manufacturing process, in particular following the assembly of the component or the voltage regulator with the associated generator.

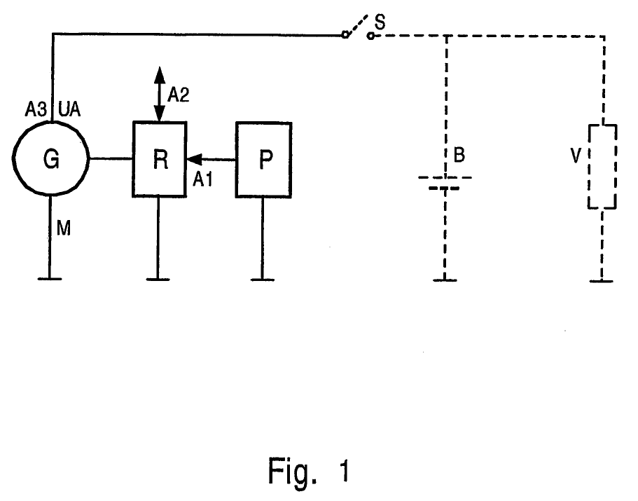

### FIELD OF THE INVENTION

The present invention relates to setting predefinable parameters which may be used, in particular, for a voltage regulator for a generator in a motor vehicle.

### BACKGROUND INFORMATION

Keeping a plurality of different components and designs of certain components in stock is expensive and may possibly result in considerable storage costs. This is also true for voltage regulators which are used for regulating the output voltage of generators, e.g., three-phase generators in motor vehicles.

Voltage regulators having an increasing variety of customer-specific and application-specific parameter settings are presently manufactured for improving the adaptation of the generator behavior to the requirements of the vehicle electrical system and the engine management in different vehicles. Since a plurality of generators having different characteristics should also be used, a particularly large number of different voltage regulators is necessary to cover all options.

Parametrization, i.e., the optimum selection of characteristics of the voltage regulator for the respective requirements, takes place presently during the manufacturing process and is no longer modifiable on the finished product, i.e., the finished voltage regulator, or even after assembly of the voltage regulator with the generator. A large variety of different voltage regulators is on the market because of this fact. In particular for the spare parts market, this means a large and still rising number of voltage regulators or components which must be kept in stock and incur costs. Even in the case of “identical parts” in terms of design, different voltage regulators differ by their parameters, for example.

A vehicle control unit having a so-called variant coding, as well as an associated control method which is designed for a variety of different vehicle variants and which has means for coding the variant, is described in, for example, German Patent Application DE 101 01 311 C2. Moreover, there are means for storing the variant coding for customizing the vehicle control unit for a predetermined vehicle variant; for example, a plurality of control parameters is stored for the different vehicle variants. The variant coding itself has a number of bit positions. The control parameters for the control method are ascertained during operation of the control unit by algorithmically processing the variant coding. This makes it possible to differentiate between large numbers of different vehicle variants using the same code word length.

### SUMMARY

A method according to an example embodiment of the present invention may make it possible to advantageously reduce the total number of components in electronic parts to be manufactured using at least one integrated circuit without having to restrict the possible variety of configurations. This reduction in components is particularly advantageous in voltage regulators which are to be used for regulating the output voltage of different types of generators in different vehicles having different electrical systems and different demands on optimum regulation and which have at least one integrated circuit. It may be particularly advantageous that, by reducing the number of regulator types without simultaneously reducing the variant variety, a substantial reduction in manufacturing costs and in particular in warehouse costs is achievable. This is particularly true in connection with the spare parts market where different voltage regulators are to be kept in stock.

These advantages may be achieved, for example, by manufacturing or providing the electronic component, e.g., a voltage regulator, initially without parametrization or with reduced parametrization. The electronic component or voltage regulator offers the option to establish the set of parameters via a suitable mechanism, in particular via an additional connection between the integrated circuit and an external processor or by using an existing interface. The electronic component or the voltage regulator may be specifically calibrated directly prior to installation on site or, in the case of a voltage regulator, after assembly of the generator and the voltage regulator.

The specific setting of a voltage regulator may be advantageously carried out on site prior to installation of the voltage regulator into the appropriate generator only when it is established which generator is involved or which characteristics should be provided for the overall system of generator-voltage regulator-electrical system. An advantageous option is achieved by programming the specific settings after assembly of the generator and the voltage regulator. For example, if the electronic component or the voltage regulator is provided from the manufacturing sector to the service departments without parametrization, then the specially adaptable parameters may be input in the service department. Spare parts for the electronic component or the voltage regulator may be kept in stock advantageously without parametrization or little parametrization and the parameters are input only after it is established which parameters are needed.

### BRIEF DESCRIPTION OF THE DRAWING

The Figure shows schematical components for carrying out a method according to an example embodiment of the present invention.

### DESCRIPTION OF EXAMPLE EMBODIMENTS

The figure schematically shows a generator G whose output voltage UA should be regulated by a regulator R, the regulator influencing the excitation current of the generator in a conventional manner in such a way that the intended output voltage UA is set. Regulator R has a terminal A1 via which it may be connected to a programming unit P. If the voltage regulator is a regulator without an interface, an additional terminal A2 specific to the application is provided via which the regulator is connectable to the rest of the electrical system or a control unit, e.g., the engine controller. In addition to the connection to the regulator, generator G has a ground connection M as well as a terminal A3 at which output voltage UA is output.

Battery B and current consumers V may be connected to terminal A3 via a switch S. These components, represented in the drawing by dashes, are not part of the example device, but only show how a device according to the present invention may be integrated into a vehicle electrical system.

In the exemplary embodiment, the voltage regulator stands for any electronic component or a spare part having at least one integrated circuit and an external access means via which the integrated circuit is influenceable.

The voltage regulator typically includes one or multiple integrated circuits (IC) which, according to the related art, are programmed during manufacturing in such a way that they later contain all necessary variables and parameters. These different variables are used for better adapting the regulator to the generator and the generator behavior to the electrical system and engine management. For this purpose, regulators are equipped with an increasing variety which results in customer-specific and application-specific parameter settings. Parametrization takes place in the related art during the manufacturing process and cannot be changed on the finished product. For the spare parts market, this means an increasing number of components which must be kept in stock and incur costs. Even in the case of “light parts” in terms of design, the voltage regulators differ by their parameters, for example.

Using the arrangement shown in the figure, having a regulator R which has an external terminal A1 to which a programming unit P is connectable, regulator R may still be reprogrammed even after manufacturing. Regulator R and its integrated circuit, which also has a suitable memory, are not programmed during IC manufacture, but rather a regulator having a so-called zero-programmed IC is manufactured. Such a regulator is operable in principle; however, it lacks the customer-specific setting or programming.

According to the example embodiment of the present invention, these values are externally programmed in the integrated circuit of the finished regulator R via interface A1 in that interface A1 is connected to a programming unit P which knows or has stored all variables and parameters necessary for the variety of regulators. The digital interface may be a frame-synchronous interface or a so-called LIN (local interconnect network) interface. For programming, the regulator IC is set into a special programming mode via the interface. This takes place, for example, by transmitting a certain bit sequence which is supplied to regulator R by programming unit P. If regulator R is in the programming mode, the data from programming unit P are transferred to the regulator and programmed into the IC of the regulator. The regulator may be locked after programming, i.e., the programming path is locked after programming so that a call of this programming mode is no longer possible and a change in the programmed data is no longer possible. All parameters which are already programmed in conventional voltage regulators for generators in vehicles during the manufacturing phase of the ICs are settable or programmable.

The possible programs and regulator settings or parameters include the following functions in particular:

Setpoint value for the regulator voltage, in particular the regulator voltage/temperature curve;

Load-response-start as a function of an engine speed threshold and/or a standby time, the term load-response-start being understood as a control strategy known per se which is selected when load is applied during start;

Load-response-drive operation as a function of a ramp steepness and/or an engine speed threshold, the term load-response-drive operation being understood as a control strategy known per se which is carried out when load is applied during normal driving operation and the transition from load-response-start to load-response-drive operation ultimately takes place as a function of the selected function parameters;

Error values or default values, if the voltage regulator is an interface regulator, i.e., a regulator which has an additional interface for the connection to the engine controller, via which data or voltages are exchangeable. For example, predefinable values for the regulator voltage, the automatic onset of vehicle movement at a certain engine speed threshold, limp-home behavior, ramp steepness (e.g., in the load-response function), an engine speed threshold (LR function), exciting current limitation, etc., and identifiers, in particular manufacturer codes or generator types or chip versions may be used as error or default values.

Further functions and parameters are possible.

In other electronic components or spare parts, other functions, variables, or parameters may also be input or modified after the final assembly. According to the example embodiments, the electronic components, e.g., voltage regulators or spare parts, initially receive a so-called zero programming, and include an integrated circuit which may be externally influenced via an interface and that for this interface the integrated circuit be programmed using a programming device, the ultimate parameters being programmed at a suitable point or at a suitable time during the course of the manufacturing process or after the manufacturing process is completed.

1-8. (canceled)

9. A method for setting predefinable parameters in an electronic component which comprises at least one integrated circuit which is connectable to an external programming device via an interface, the method comprising:
during manufacturing, the integrated circuit receiving a zero programming; and
connecting the integrated circuit to the external programming device only after the manufacturing is completed.

10. The method as recited in claim 9, further comprising:
transferring predefinable parameters or settings from the programming device to a memory device of the integrated circuit, the predefinable parameters or settings being ultimate parameters of the integrated circuit.

11. The method as recited in claim 9, further comprising:
setting the integrated circuit into a programming mode for programming or write-in.

12. The method as recited in claim 10, further comprising:
after completion of the transfer of the predefinable parameters or settings, interrupting the connection to the programming unit and locking a programming path.

13. The method as recited in claim 9, wherein the manufacturing includes manufacturing a voltage regulator for a generator, and further comprising:
programming the voltage regulator on-site prior to assembly of the voltage regulator and the generator, the programming occurring after selection of the generator and establishment of system characteristics of an overall generator-voltage regulator-vehicle electrical system.

14. The method as recited in claim 9, wherein the manufacturing includes manufacturing a voltage regulator for a generator, and further comprising:
programming the voltage regulator after assembly of the generator and the voltage regulator.

15. The method as recited in claim 10, wherein the predefinable parameters or settings include:
at least one of setpoint value for a regulator voltage/temperature curve;
load- response-start as a function of at least one of an engine speed threshold and a standby time, the term load-response-start being a control strategy which is selected when load is applied during start;
load-response-drive operation as a function of at least one of a ramp steepness and an engine speed threshold, the load-response-drive operation being as a control strategy which is carried out when load is applied during normal driving operation and a transition from load-response-start to load-response-drive operation ultimately takes place as a function of selected function parameters; and
error values or default values.

16. A device for setting predefinable parameters in an electronic component which includes at least one integrated circuit having a zero programming, comprising:
an external programming device configured to connect to the integrated circuit only after a manufacturing process is complete, the external programming device configured to transfer predefinable parameters or settings to a memory device of the integrated circuit.
